(19) United States
(12) Patent Application Publication
(10) Pub. No.: US 2010/0283478 A1
(43) Pub. Date: Nov. 11, 2010

(54) CONNECTOR CONDUCTION CHECK APPARATUS

(75) Inventor: Hideyuki Katoh, Shizuoka (JP)

Correspondence Address: SUGHRUE-265550, 2100 PENNSYLVANIA AVE. NW, WASHINGTON, DC, 20037-3213, US

(73) Assignee: YAZAKI CORPORATION, Tokyo (JP)

(21) Appl. No.: 12/810,532

(22) PCT Filed: Dec. 26, 2008
(86) PCT No.: PCT/JP2008/073971

§ 371 Date: Jun. 25, 2010

(30) Foreign Application Priority Data
Dec. 28, 2007 (JP) 2007-341198

(51) Int. Cl. G01R 31/04

(52) U.S. Cl. 324/538

(57) ABSTRACT

The object of the present invention is to provide a connector conduction check apparatus manufactured easily and inexpensively. The connector conduction check apparatus of the present invention 1 includes a main body 10 having a plate member 17, a rail part 27 formed by bending the plate member 17, an inspection part 12 having a plurality of inspection pins 19 to be connected to the connector 2 and a rail part guide 28 formed on the inspection part 12 and in which the rail part 27 is fitted so that the inspection part 12 slides along the rail part guide 28.

### TECHNICAL FIELD

The present invention relates to a connector conduction check apparatus configured to hold a connector of a wire harness and to be able to have electrical conduction to the connector of the wire harness with terminals when an electrical conduction test for the wire harness is performed.

### BACKGROUND ART

All this time, the quality of a wire harness provided with a plurality of electric wires and a connector accommodating terminals which are respectively connected to ends of the electric wires is checked by confirming whether each of the terminals has electrical conduction to other respective terminals.

Hitherto, a method of inspecting the wire harness of this type has been performed by the following procedure. That is, one of the terminals of the wire harness is first selected. Then, electricity is applied to the selected terminal to thereby determine whether potential of each of the other terminals is high or low. The electricity is applied to all the terminals in order. Then, in all cases, the potentials of all terminals other than the terminal to which the electricity is applied are determined in order. Thus, the mutual electrical conduction among all the terminals is checked.

The mutual electrical conduction among the terminals, which is checked as described above, is compared with the mutual electrical conduction among the terminals in a case where the wire harness is normal. Thus, the quality of the wire harness is checked. If the wire harness is abnormal, an abnormal portion is grasped.

As described above, check apparatuses configured to hold the connector are hitherto used to inspect wire harnesses (see, e.g., JP-H08-320355, JP-2002-343527). The check apparatus of this type includes a body having one end part to and from which a connector is attachable and detachable, an operating lever rotatably attached to the other end part of the body, an inspecting part movably provided on the body, a link configured to interlock rotation of the operating lever with movement of the inspecting part, and a guide portion configured to guide the movement of the inspecting part with respect to the body.

The inspecting part has inspecting pins each of which is electrically contacted with (i.e., have conduction with) a terminal of the connector. The inspecting part is provided movably with respect to the body between an inspecting position and an attachment-detachment position. At the inspecting position, the inspecting pin is electrically connected to the terminal with the connector set between the inspecting part and the one end of the body. At the attachment-detachment position, the inspecting part is located to the other end part of the body and at which the connector is detachable therefrom.

The aforementioned check apparatus described in JP-H08-320355 and JP-2002-343527 is operated as follows. That is, the inspecting part is first placed at the attachment-detachment position using the operating lever. Then, the connector is attached to the one end part of the body. Subsequently, the inspecting part is moved to the inspecting position using the operating lever. Then, in the check apparatus, each of the inspecting pins is electrically connected to an associated one of the terminals. Thus, electricity is applied to the terminals via the inspecting pins in order. Consequently, the quality of the wire harness is checked. Additionally, when the wire harness is abnormal, an abnormal portion is grasped. Subsequently, the inspecting part is placed at the attachment-detachment position again using the operating lever. The inspected connector is removed from the body. Similarly to the aforementioned process, a conduction test is performed on an untested connector.

In the aforementioned check apparatus described in JP-H08-320355, the guide portion is constituted by cross-sectionally hook-like shaped rails attached to the bottom surface of the body, and cross-sectionally hook-like grooves provided in the inspecting part. The guide portion guides the direction of movement of the inspecting part with respect to the body by passing the rails through the grooves, respectively. Thus, in the check apparatus described in JP-H08-320355, the shapes of the rails and the grooves are complex. Therefore, the number of man-hours for forming each of the rails and the grooves in an associated one of the body and the inspecting part tend to increase.

Further, in the aforementioned check apparatus described in JP-2002-343527, the guide portion is constituted by rails mounted on inner surface of a pair of side walls erected from the bottom surface of the body and grooves concavely provided in side surfaces of the inspecting part. The guide portion guides the direction of movement of the inspecting part with respect to the body by passing the rails through the grooves, respectively. In the check apparatus described in JP-2002-343527, the rails are formed separately from the side walls. Each of the rails is fixed to the center in the direction of thickness of (i.e., a direction protruding from) an associated one of the side walls with screws or the like. Thus, the check apparatus described in JP-2002-343527 has a tendency towards increase in the number of components, and accordingly increase in the cost thereof.

Accordingly, an object of the invention is to provide a connector conduction check apparatus manufactured easily and inexpensively.

### DISCLOSURE OF THE INVENTION

To solve the aforementioned problems and to achieve the object of the invention, the present invention provides a connector conduction check apparatus of the following configuration. The first aspect of the invention is the connector conduction check apparatus including a main body having a plate member, a rail part part formed by bending the plate member, an inspection part having a plurality of inspection pins to be connected to the connector and a rail part guide formed on the inspection part and in which the rail part is fitted so that the inspection part slides along the rail part guide from a first position to a second position.

Preferably, in the above configuration, the rail part is formed by bending an edge of the plate member.

Preferably, in the above configuration, the inspection part has a side surface on which the edge of the plate member contacts with the inspection part. The rail part guide is formed on the side surface.

Preferably, in the above configuration, the inspection part has a guide shaft and a cover having a guide hole through which the guide shaft inserted and guides the cover.

Preferably, the inspection part further includes a cover covering a tip of each of the inspecting pin when the inspecting part is at the first position and a guide shaft along which the cover slides during the inspecting part movement between the first and the second position.

Preferably, in the above configuration, the cover has a plurality of pin holes through each of which respective one of the inspection pins juts out and is retracted during the cover movement.

The second aspect of the invention according to the first aspect is that the conduction check apparatus of the first aspect further includes a lever connected to the inspection part by a link at a rotatable connection and rotatably connected to the main body.

Preferably, the rotatable connection comes into contact with the main body.

Preferably, the ratable connection comes into contact with the main body at the rail part.

According to the first aspect of the connector conduction check apparatus of the invention, the rails of the guide portion for guiding movement are formed by folding edge parts of a pair of side plate portions, which position the inspecting part therebetween, in a direction, in which the pair of side wall portions are made closer to each other. Thus, each of the rails can be formed by folding the edge part of an associated one of the side wall portions. In addition, each of the rails can be formed integrally with the associated one of the side wall portions.

According to the second aspect of the connector conduction check apparatus of the invention, the movement restricting portion includes a top surface of each of the rails, and an end portion of the link which is connected to the operating lever. When the inspecting part is placed at the inspecting position, the top surface of each of the rails is contacted with the end portion of the link. Thus, when the end portion of the link is contacted with the top surface of an associated one of the rails, the operating lever cannot rotate in a direction in which the inspecting part moves further closer to the side of the one end part, in a state in which the inspecting part is placed at the inspecting position, because the end portion of the link is attached to the operating lever.

As described above, according to the first connector conduction check apparatus of the invention, each of the rails can be formed by bending the edge part of the associated one of the side plate portions. In addition, each of the rails can be formed integrally with the associated one of the side plate portions. Thus, the rails can easily be manufactured without increasing the number of components. Consequently, the invention can provide a connector conduction check apparatus manufactured easily and inexpensively.

According to the second aspect of the connector conduction check apparatus of the invention, when the inspecting part is placed at the inspecting position, the operating lever cannot rotate in a direction in which the inspecting part moves further closer to the side of the one end part. Accordingly, the inspecting part placed at the inspecting position can surely be prevented from moving further closer to the side of the one end part to thereby damage a connector.

### BRIEF DESCRIPTION OF THE DRAWINGS

FIG. 1 is a perspective view illustrating a connector conduction check apparatus according to an embodiment of the invention.

FIG. 2 is a side view illustrating a state in which a conduction inspecting part of the connector conduction check apparatus illustrated in FIG. 1 is placed at an attachment/detachment position.

FIG. 3 is a side view illustrating a state in which the conduction inspecting part of the connector conduction check apparatus illustrated in FIG. 2 is moved towards an inspecting position.

FIG. 4 is a side view illustrating a state in which the conduction inspecting part of the connector conduction check apparatus illustrated in FIG. 3 is placed at the inspecting position.

FIG. 5 is a perspective view illustrating the conduction inspecting part of the connector conduction check apparatus illustrated in FIG. 1.

FIG. 6 is a cross-sectional view illustrating the configuration of a guide portion of the connector conduction check apparatus illustrated in FIG. 1.

### BEST MODE FOR CARRYING OUT THE INVENTION

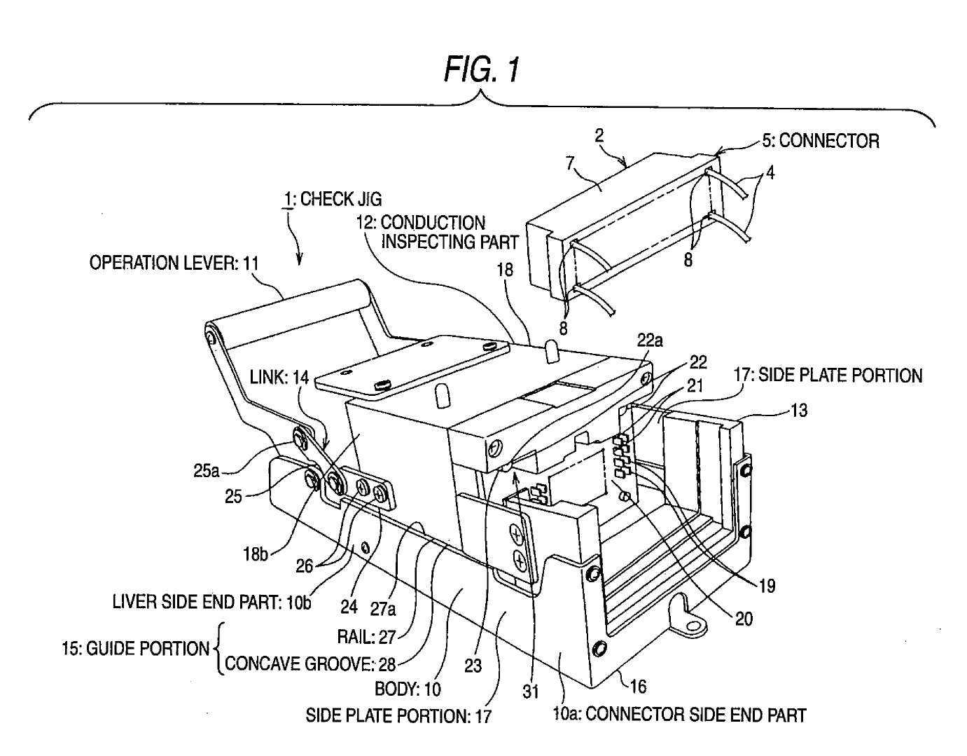

Hereinafter, a connector conduction check apparatus according to an embodiment of the invention is described by referring to FIGS. 1 to 6. The connector conduction check apparatus (hereunder referred to simply as the check apparatus) 1 according to the present embodiment of the invention is used when a conduction test is performed on a wire harness 3. As illustrated in FIG. 1, the wire harness 3 includes a plurality of electric wires 4, and a plurality of connectors 5 (FIG. 1 illustrates only one of the connectors 5).

Each of the electric wires 4 is what is called a covered wire including an electrically conductive core wire and an insulating covering portion that covers the core wire. The connector 5 includes a terminal (not shown) and a connector housing 7. The terminal is obtained by folding an electrically conductive metal plate. The terminal is attached to an end portion of the electric wire 4 so as to be electrically connected to the core wire. The connector housing 7 is made of an insulating synthetic resin and is formed like a box. The connector housing 7 includes a plurality of terminal accommodating chambers 8 in each of which the terminal is accommodated.

A wire harness 3 of such a configuration is arranged in an automobile. The connector 5 of each of the wire harness 3 is connector-connected to a connector of an electronic device mounted on the automobile. The wire harness 3 transmits to the electronic device electric power output from a power supply, such as a battery, or a control signal sent from a control apparatus.

As illustrated in FIG. 1, the check apparatus 1 includes a body 10 mounted on an inspecting table or the like, a connector receiving part 13, an operation lever 11, a conduction inspecting part 12 serving as the inspecting part, a link 14, and a guide portion 15.

The body 10 is constructed by folding a thick metal plate or the like, and includes a rectangular bottom plate part 16 and a pair of side plate portions 17, which are formed integrally with one another. The side plate portions 17 are erected from both edges in the direction of width of the bottom plate part 16 of the body 10. A pair of the side plate portions 17 is arranged in parallel to each other by being spaced from each other. Further, a shaft 30 (which is illustrated in FIG. 6) for guiding the conduction inspecting part 12 is fixed to the bottom plate part 16. The shaft 30 is cylindrically formed and disposed to set the longitudinal direction thereof to be parallel to that of the both portion 10. In addition, both end parts of the shaft 30 are fixed to the bottom plate part 16.

The connector receiving portion 13 is attached to connector side end part 10a in the longitudinal direction of the body 10. The connector receiving portion 13 is formed into U-shape to be superimposed with the bottom plate part 16 and the pair of side plate parts 17. The connector receiving portion 13 holds the connector 5 in a state in which an opening portion of each of the terminal accommodating chambers 8 faces the conduction inspecting part 12. In an example illustrated in these drawings, the connector 5 is adapted to be able to be taken out of and put into the connector receiving portion 13 along a vertical direction perpendicular to the bottom plate part 16.

The operation lever 11 is supported so that one edge portion of one end part thereof (herein after refere the one end portion as the first lever edge portion) is rotatable around the lever side end part 10b of the body 10. The operation lever 11 is rotatably attached to the side plate portions 17.

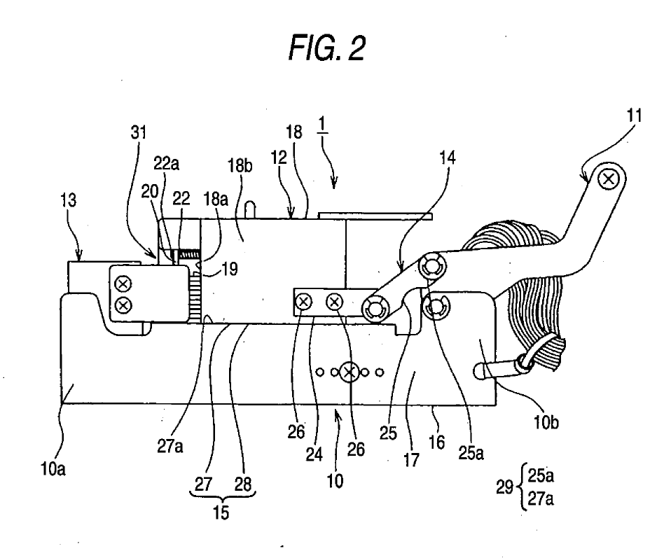

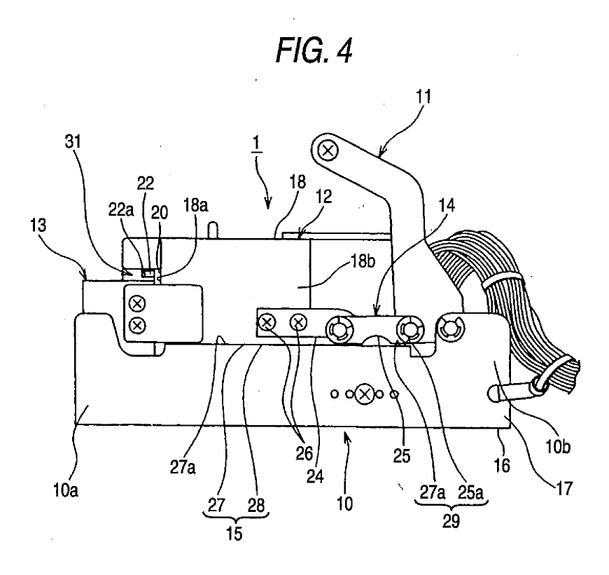

The conduction inspecting part 12 is provided at a central part in the longitudinal direction of the body 10. As illustrated in FIG. 1, the conduction inspecting part 12 includes an inspecting part body 18, a plurality of inspecting pins 19, and a cover plate 20. The inspecting part body 18 is formed like a hexahedron. The inspecting part body 18, i.e., the conduction inspecting part 12 is provided on the bottom plate part 16 of the body 10 and between the pair of the side plate portions 14 slidably in a direction in which the conduction inspecting part 12 moves towards and away from the connector receiving portion 13 (i.e., contactably with and separatably from the connector receiving portion 13) between an inspecting position illustrated in FIG. 4, at which the connector 5 is placed between the inspecting part 12 and the connector receiving portion 13, i.e., the connector side end part 10a, and an attachment-detachment position illustrated in FIG. 2, at which the inspecting part 12 is located closer to the lever side end part 10b of the body 10 than the inspecting position, and at which the connector 5 is attachable to and detachable from the connector receiving portion 13, i.e., the connector side end part 10a of the body 10. Thus, the inspecting part body 18, i.e., the conduction inspecting part 12 is provided movably along the longitudinal direction of the body 10.

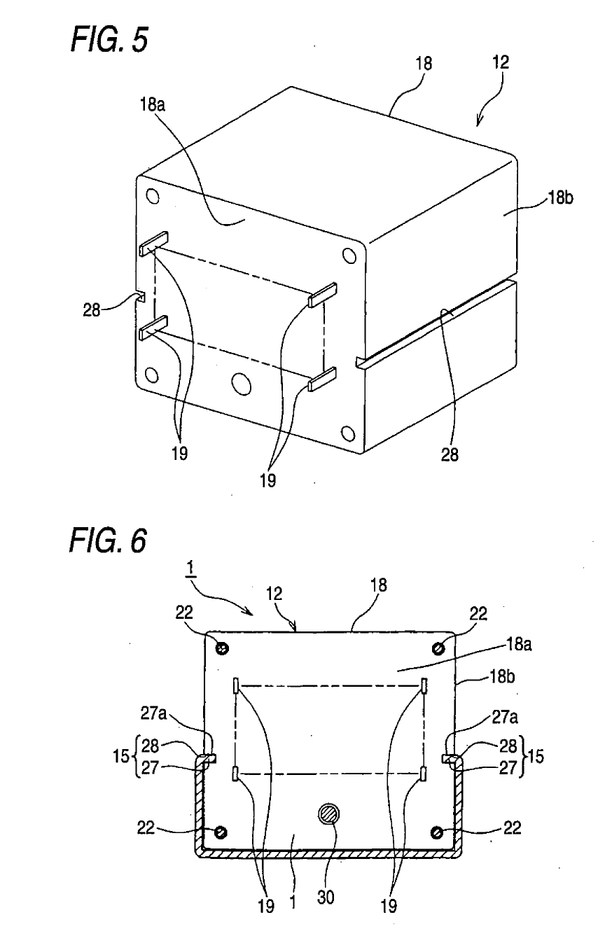

Each of the inspecting pins 19 is formed like a rod extending linearly. The inspecting pins 19 are arranged in parallel to one another by being spaced apart from one another. The inspecting pins 19 are arranged to be parallel to the longitudinal direction of the body 10. In addition, each of the inspecting pins 19 is attached to the inspecting part body 18 such that one end part thereof protrudes from an end surface 18a of the inspecting part body 18 facing the connector receiving portion 13, as illustrated in FIG. 5. Additionally, a conduction inspecting device (not shown) is connected to the other end part of each of the inspecting pins 19.

A cover plate 20 is formed like a thick flat-plate. A plurality of through holes 21, through each of which an end part of an associated one of the inspecting pins 19 is passed, are provided in the cover plate 20. The cover plate 20 is disposed in parallel to the aforementioned end surface 18a by passing the one end part of each of the inspecting pins 19 through an associated one of the through holes 21 and by being spaced apart from the end surface 18a. In addition, the cover plate 20 is attached by a plate slide support portion 31 to the inspecting part body 18 movably along the longitudinal direction of the body 10.

The plate slide support portion 31 includes cylindrical guide shafts 22 attached to four corners of the inspecting part body 18, guide holes 23 passing through the cover plate 20, and coil springs. One end portion of each of the guide shafts 22 is attached to the inspecting part body 18, while the other end portion thereof is passed in an associated one of the guide holes 23. Further, each of the guide shafts 22 is provided with a large-diameter portion 22a at an end of the other end portion thereof. The outside diameter of the large-diameter portion 22a is larger than the inside diameter of an associated one of the guide holes 23. Each of the large-diameter portions 22a is disposed so as to place the cover plate 20. In addition, the end surface 18a and the large-diameter portion 22a are superimposed on a surface of the cover plate 20. Each of the large-diameter portions 22a restricts the cover plate 20 from slipping off an associated one of the guide shafts 22. Each of the coil springs urges the cover plate 20 in a direction in which the cover plate 20 is moved away from the end surface 18a of the inspecting part body 18.

The link 14 includes a pair of fixed link members 24 and a pair of rotating link members 25. Each of the link members 24 is formed like a short bar, and is disposed to set the longitudinal direction thereof to be parallel to that of the body 10. Each of the fixed link members 24 is fixed to a side surface 18b (corresponding to the side surface of the conduction inspecting part 12) with screws 26 or the like so that one end part thereof protrudes from the inspecting part body 18. Here, the side surface 18b overlaps with the side plate portions 17 of the inspecting part body 18 of the conduction inspecting part 12,

Each of the rotating link members 25 is formed like a short bar. One end portion in the longitudinal direction of each of the rotating link members 25 is rotatably connected to one end portion of an associated one of the fixed link members 24 (Hereinafter, refer the one end portion as the body side end portion). The other end portion 25a in the longitudinal direction of each of the rotating link members 25 is rotatably connected to the other edge part of the one end portion of the operation lever 11 (Hereinafter, refer the other end portion as the lever side end portion and refer the other edge part as the second lever edge portion). The lever side end portion 25a is an end portion of the link 14, which corresponds to the end portion of the link connected to the operation lever 11 described as the second aspect of the present invention.

Each of the body side end portion is rotatably connected to the respective one end portion of the fixed link members 24. The lever side end portion 25a is rotatably connected to the second lever edge portion. Thus, when the operation lever 11 is rotated around the body side end portion, the link 4 causes the conduction inspecting part 12 to move along the longitudinal direction of the body 10. The link 14 interlocks the rotation of the operation lever 11 with the movement of the conduction inspecting part 12 with respect to the body 10.

As illustrated in FIG. 6, the guide portion 15 includes a pair of rails 27 and a pair of concave grooves 28. Each of the rails 27 is formed by bending an edge part of the side plate portion 17, which is opposite side edge to the bottom plate part 16 of this side plate portion 17, in a direction in which the pair of side wall portions 17 are made closer to each other. That is, each of the rails 27 is formed integrally with and constitutes a part of the associated side plate portion 17. Each of the rails 27 linearly extends along the longitudinal direction of the body 10 and is formed on the longitudinally central portion of the associated side plate portion 17 other than both the end portions 10a and 10b of the body 10.

As illustrated in FIGS. 5 and 6, each of the paired concave grooves 28 is concavely formed in an associated one of the aforementioned side surfaces 18b of the inspecting part body 18 of the conduction inspecting part 12. Each of the concave grooves 28 linearly extends along the longitudinal direction of the body 10. In addition, each of the concave grooves 28 is provided over the entire length of the associated side surface 18b. Each of the rails 27 enters and slides along the associated one of the concave grooves 28.

The aforementioned guide portion 15 movably supports the inspecting part body 18, that is, the conduction inspecting part 12. And also, the guide portion 15 guides the movement of the inspecting part body 18, that is, the movement of the conduction inspection part 12 in the longitudinal direction of the rails 27. This movement is corresponding to the movement of the body 10 respective to the body 10. The above functions of the guide portion are realized by that the each of the rails 27 is inserted into and slides along the associated one of the concave grooves.

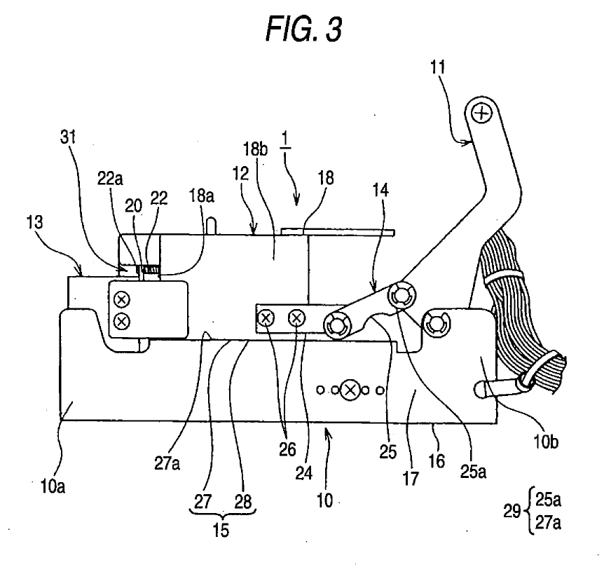

In the check apparatus 1 of the aforementioned configuration, as illustrated in FIG. 2, the conduction inspecting part 12 is at the attachment-detachment position which is most distant position from the connector receiving portion 13 when the other end part of the operating lever 11 is parallel to the longitudinal direction of the body 10 and protruded from the other side end part of the body. Then, when the other end part of the operation lever 11 is rotated about the one end part of the operation lever 11 so as to be close to the connector receiving portion 13, the conduction inspecting part 12 is pushed by the link 14 towards the connector receiving portion 13, that is, towards the connector receiving portion 13. Then the check apparatus 1 changes from the attachment-detachment position to the inspecting position, as illustrated in FIG. 3.

At this inspecting position, as illustrated in FIG. 4, the lever side end portion is contacted with the top surface 27a of an associated one of the rails 27. Further, the longitudinal direction of each of the rotating link members 25 and the fixed link members 24 becomes parallel to the longitudinal direction of the body 10. In addition, each of the rotating link members 25 is contacted with the top surface 27a of the associated rail 27 over the entire length thereof. Thus, at the inspecting position, the lever side end portion is contacted with the top surface 27a of the associated rail 27. Consequently, the operation lever 11 is restricted from being further rotated in a direction in which the conduction inspecting part 12 moves further closer to the connector receiving portion 13. Thus, the aforementioned lever side end portion 25a and the top surface 27a of each of the rails 27 constitute a movement regulating portion 29 that restricts the conduction inspecting part 12 from moving towards the connector receiving portion 13, i.e., closer to the side of one end portion 10a of the body 10 than the inspecting position.

When a conduction check is performed on the wire harness 3 using the check apparatus 1 of the aforementioned configuration, the operation of the check apparatus 1 is as below. At first, as illustrated in FIG. 2, the connector 5 is attached to (or held at) the connector receiving portion 13, in other words, the one end portion 10a of the body 10 while the conduction inspecting part 12 is placed at the attachment-detachment position. The conduction inspecting part 12 is made closer to the connector receiving portion 13 by rotating the operation lever 11.

Then, the inspecting pins 19 enter the inside of the terminal accommodating chambers 8 of the connector 5 attached to the connector receiving portion 13. In addition, the cover plate 20 is contacted with the connector receiving portion 13 and the connector 5 attached to this connector receiving portion 13. Thus, movement of the cover plate 20 is regulated. After that, when the operation lever 11 is further rotated, the conduction inspecting part 12 is moved close to the cover plate 20 against an urging force of the coil springs. Coincidentally, the inspecting pin 19 protrudes from the cover plate 20 and is contacted with the terminals in the terminal accommodating chambers 8. Then, the cover plate 20 comes into contact with the conduction inspecting part 12. Furthermore, as illustrated in FIG. 4, the lever side end portion 25a is contacted with the top surface 27a of the associated rail 27, so that the conduction inspecting part 12 is placed at the inspecting position.

Thus, electrical conduction between each terminal of the connector 5 and an associated one of the inspecting pins 19 can be assured. The aforementioned conduction inspecting device applies electricity to the terminals via the inspecting pins 19 in order. Thus, the conduction inspecting device grasps the state of the electrical conduction among the terminals. Then, the conduction inspecting device compares the grasped state of the electrical conduction therebetween with that of the electrical conduction among the terminals in a case where the wire harness 3 is normal. Consequently, the quality of the wire harness 3 is determined. Thus, the conduction inspecting device 1 performs a conduction test on the connector 5 at the inspecting position.

According to the present embodiment, the rails 27 of the guide portion 15 for guiding movement of the conduction inspecting part 12 are formed by folding edge parts of a pair of the side plate portions 17 in a direction, in which the pair of side wall portions 17 is made closer to each other. Thus, each of the rails can be formed by folding the edge part of the associated one of the side plate portions 17. In addition, each of the rails 27 can be formed integrally with the associated one of the side plate portions. Thus, the rails 27 can easily be manufactured without increasing the number of components. Consequently, the present embodiment can provide a connector conduction check apparatus 1 manufactured easily and inexpensively.

The movement regurating portion 29 includes the top surface 27a of each of the rails 27, and the lever side end portion 25a of the link 25 which is connected to the operation lever 11, and the top surface 27a and the lever side end portion 25a are in contact with each other. Thus, when the lever side end portion 25a of each of the is contacted with the top surface 27a of an associated one of the rails 27, the operation lever 11 cannot rotate in a direction, in which the conduction inspecting part 12 moves further closer to the side of the connector side end part 10a, i.e., the side of the connector receiving portion 13, in a state, in which the conduction inspecting part 12 is placed at the inspecting position, because the end portion of each of the rotating link members is attached to the operation lever 11. Accordingly, the conduction inspecting part 12 placed at the inspecting position can surely be prevented from moving further closer to the side of the connector side end part 10a to thereby damage the connector 5.

Incidentally, in the foregoing description of the embodiment of the invention, only an exemplary embodiment has been described. The invention is not limited to the aforementioned embodiment. That is, the invention can be implemented by variously being modified without departing from the gist thereof.

1. A conduction check apparatus for inspecting conduction of a connector comprising:
a main body having a plate member;
a rail part formed by bending the plate member;
an inspection part having a plurality of inspection pins to be connected to the connector; and
a rail part guide formed on the inspection part and in which the rail part is fitted so that the inspection part slides along the rail part guide from a first position to a second position.

2. The conduction check apparatus according to claim 1, wherein the rail part is formed by bending an edge of the plate member.

3. The conduction check apparatus according to claim 2, wherein the inspection part has a side surface on which the edge of the plate member contacts with the inspection part, wherein the rail part guide is formed on the side surface.

4. The conduction check apparatus according to claim 1, further comprises a lever connected to the inspection part by a link at a rotatable connection and rotatably connected to the main body.

5. The conduction check apparatus according to claim 4, wherein the rotatable connection comes into contact with the main body in the second position.

6. The conduction check apparatus according to claim 5, where in the first rotatable connection comes into contact with the main body at the rail part in the second position.

7. The conduction check apparatus according to claim 1, wherein the inspection part has a guide shaft and a cover having a guide hole through which the guide shaft inserted and guides the cover.

8. The conduction check apparatus according to claim 7, wherein the inspection part further comprises a cover covering a tip of each of the inspecting pin when the inspecting part is at the first position and a guide shaft along which the cover slides during the inspecting part movement between the first and the second position.

9. The conduction check apparatus according to claim 8, wherein the cover has a plurality of pin holes through each of which respective one of the inspection pins juts out and is retracted during the cover movement.
